(19) United States
(12) Patent Application Publication
(10) Pub. No.: US 2024/0372514 A1
(43) Pub. Date: Nov. 7, 2024

(54) AMPLIFIER CIRCUIT

(71) Applicant: SUMITOMO ELECTRIC INDUSTRIES, LTD., Osaka (JP)

(72) Inventor: Hirotaka ASAMI, Osaka-shi (JP)

(73) Assignee: SUMITOMO ELECTRIC INDUSTRIES, LTD., Osaka (JP)

(21) Appl. No.: 18/646,042

(22) Filed: Apr. 25, 2024

(30) Foreign Application Priority Data
May 1, 2023 (JP) 2023-075737

(51) Int. Cl. H03F 3/24; H03F 1/02; H03F 1/56

(52) U.S. Cl. CPC H03F 3/245; H03F 1/0288; H03F 1/56

(57) ABSTRACT

An amplifier circuit includes a first divider, a control amplifier, an auxiliary amplifier, a load modulation circuit, and a stub configured to include a left-handed line, and an end connected to a node in at least one of a first line connecting the control amplifier to the load modulation circuit and a second line connecting the auxiliary amplifier to the load modulation circuit, wherein when any frequency in an operating band is set as a fundamental wave and an impedance when the stub is viewed from the node is represented on a Smith chart, an impedance in a second harmonic wave is located at a first point where the impedance is short, and an impedance in a third harmonic wave rotates clockwise from the first point and is located at a point rotated by a smaller angle than a second point where the impedance is open.

### CROSS REFERENCE TO RELATED APPLICATIONS

This application claims priority based on Japanese Patent Application No. 2023-075737 filed on May 1, 2023, and the entire contents of the Japanese patent applications are incorporated herein by reference.

### FIELD

The present disclosure relates to an amplifier circuit.

### BACKGROUND

It is known that a left-handed line is used for an impedance matching circuit of an amplifying circuit that amplifies a high-frequency signal such as a microwave (for example, Japanese National Publication of International Patent Application No. 2012-518373).

### SUMMARY

An amplifier circuit according to the present disclosure includes: a first divider configured to divide an input signal into a first signal and a second signal; a control amplifier configured to amplify the first signal and output an amplified signal as a third signal; an auxiliary amplifier configured to amplify the second signal and output an amplified signal as a fourth signal; a load modulation circuit configured to modulate a load of the auxiliary amplifier by using the third signal, combine the third signal and the fourth signal, and output a combined signal as an output signal; and a stub configured to include a left-handed line, and an end connected to a node in at least one of a first line connecting the control amplifier to the load modulation circuit and a second line connecting the auxiliary amplifier to the load modulation circuit; wherein when any frequency in an operating band is set as a fundamental wave and an impedance when the stub is viewed from the node is represented on a Smith chart, an impedance in a second harmonic wave is located at a first point where the impedance is short, and an impedance in a third harmonic wave rotates clockwise from the first point and is located at a point rotated by a smaller angle than a second point where the impedance is open.

An amplifier circuit according to the present disclosure includes: an amplifier configured to amplify an input signal and output an amplified signal to an output terminal; and a stub configured to include a left-handed line, and an end connected to a node in a line between the amplifier and the output terminal; wherein when any frequency in an operating band is set as a fundamental wave and an impedance when the stub is viewed from the node is represented on a Smith chart, an impedance in a second harmonic wave is located at a first point where the impedance is short, and an impedance in a third harmonic wave rotates clockwise from the first point and is located at a point rotated by a smaller angle than a second point where the impedance is open.

### BRIEF DESCRIPTION OF DRAWINGS

FIG. 1 is a circuit diagram of an amplifier circuit according to a first embodiment.

FIG. 2 is a circuit diagram illustrating an example of a circuit of a hybrid coupler according to the first embodiment.

FIG. 3 is a circuit diagram of an amplifier circuit according to a first comparative example.

FIG. 4 is a circuit diagram illustrating an example of a harmonic processing circuit according to the first embodiment.

FIG. 5 is a diagram illustrating frequencies with respect to phases in a λ/4 short stub and a λ/8 open stub of a right-handed system.

FIG. 6 is a Smith chart illustrating an impedance Z when the λ/4 short stub of the right-handed system is viewed from a node N0.

FIG. 7 is a Smith chart illustrating an impedance Z when the λ/8 open stub of the right-handed system is viewed from the node N0.

FIG. 8 is a circuit diagram of a stub in the first embodiment.

FIG. 9 is a diagram illustrating frequencies with respect to phases in stubs A and B.

FIG. 10 is a Smith chart illustrating an impedance Z when the stub A is viewed from the node N0.

FIG. 11 is a Smith chart illustrating an impedance Z when the stub B is viewed from the node N0.

FIG. 12 is a diagram illustrating the passing characteristics of a line having the λ/8 open stub, a line having the stubs A, and a line having the stub B.

FIG. 13 is a diagram illustrating frequencies with respect to phases in stubs B and C.

FIG. 14 is a Smith chart illustrating the impedance Z when the stub C is viewed from the node N0.

FIG. 15 is a diagram illustrating the passing characteristics of a line having the λ/8 open stub, a line having the stub B, and a line having the stub C.

FIG. 16 is a diagram illustrating |S21| with respect to frequencies of the line having the λ/8 open stub, the line having the stub B, and the line having the stub C in simulation.

FIG. 17 is a circuit diagram of a stub in a second modification of the first embodiment.

FIG. 18 is a diagram illustrating frequencies with respect to phases in stubs B and D.

FIG. 19 is a circuit diagram of an amplifier circuit according to a second embodiment.

### DETAILED DESCRIPTION OF EMBODIMENTS

In an amplifier circuit, widening the operating band is required. For example, in the case of a load modulation type amplifier, the operating band can be widened. However, it is difficult to widen the band of the harmonic processing circuit that processes the second harmonic wave of the operating band, and it is difficult to widen the band of the amplifier circuit.

The present disclosure has been made in view of the above problems, and it is an object of the present disclosure to provide an amplifier circuit capable of widening a band.

### Details of Embodiments of the Present Disclosure

First, the contents of the embodiments of this disclosure are listed and explained.

(1) An amplifier circuit according to the present disclosure includes: a first divider configured to divide an input signal into a first signal and a second signal; a control amplifier configured to amplify the first signal and output an amplified signal as a third signal; an auxiliary amplifier configured to amplify the second signal and output an amplified signal as a fourth signal; a load modulation circuit configured to modulate a load of the auxiliary amplifier by using the third signal, combine the third signal and the fourth signal, and output a combined signal as an output signal; and a stub configured to include a left-handed line, and an end connected to a node in at least one of a first line connecting the control amplifier to the load modulation circuit and a second line connecting the auxiliary amplifier to the load modulation circuit; wherein when any frequency in an operating band is set as a fundamental wave and an impedance when the stub is viewed from the node is represented on a Smith chart, an impedance in a second harmonic wave is located at a first point where the impedance is short, and an impedance in a third harmonic wave rotates clockwise from the first point and is located at a point rotated by a smaller angle than a second point where the impedance is open. This can widen the band of attenuation in the second harmonic wave. In addition, the insertion loss in the fundamental wave can be suppressed. Therefore, the band of the amplification circuit can be widened.

(2) In the above (1), when the impedance when the stub is viewed from the node is represented on the Smith chart, an impedance in a fourth harmonic wave may rotate clockwise from the first location and may be located at the second point or a point rotated by a smaller angle than the second point. This can widen the band of attenuation in the second harmonic wave.

(3) In the above (1) or (2), when the impedance when the stub is viewed from the node is represented on the Smith chart, an impedance in the fundamental wave may rotate clockwise from the first point and may be located at the second point. This can suppress the insertion loss in the fundamental wave.

(4) In the above (1) or (2), when the impedance when the stub is viewed from the node is represented on the Smith chart, an impedance in the fundamental wave may rotate clockwise from the first point and may be located at a point rotated by a larger angle than the second point. This can widen the band of attenuation in the second harmonic wave.

(5) In any one of the above (1) to (4), the node may be provided in the second line. This can suppress the second harmonic wave of the signal amplified by the auxiliary amplifier over a wide band.

(6) In the above (5), no matching circuit for matching impedances may be provided in the second line. This can reduce the size of the amplifier circuit.

(7) In any one of the above (1) to (6), the amplifier circuit further may include a second divider configured to divide the second signal into a fifth signal and a sixth signal whose phase is delayed by 90 degrees from the fifth signal. The auxiliary amplifier may include a first amplifier that amplifies the fifth signal and outputs an amplified signal as a seventh signal, and a second amplifier that amplifies the sixth signal and outputs an amplified signal as an eighth signal, and the load modulator may include a hybrid coupler including a first end to which the seventh signal is input, a second end to which the eighth signal is input, a third end that is located diagonally opposite to the second end and to which the third signal is input, and a fourth end that is located diagonally opposite to the first end and to which the output signal is output. This can widen the band of the load modulation circuit.

(8) In any one of the above (1) to (6), the load modulation circuit may include a first end to which the fourth signal is input, a second end to which the third signal is input, and a third end to which the output signal is output, and a signal input to the first end may be passed through the third end but not through the second end, and a signal input to the second end may be passed through the first end but not through the third end. This can widen the band of the load modulation circuit.

(9) In any one of the above (1) to (8), the left-handed line may include: a first cell including a first capacitor connected in series and a first inductor connected in shunt between the node and a tip of the stub; and a second cell including a second capacitor connected in series and a second inductor connected in shunt between the first cell and the tip of the stub. This can widen the band of the amplifier circuit.

(10) In any one of the above (1) to (8), the left-handed line may include: a first cell including a first capacitor connected in series and a first inductor connected in shunt between the node and a tip of the stub; a second cell including a second capacitor connected in series and a second inductor connected in shunt between the first cell and the tip of the stub; and a third cell including a third capacitor connected in series and a third inductor connected in shunt between the second cell and the tip of the stub. This can widen the band of the amplifier circuit.

(11) An amplifier circuit according to the present disclosure includes: an amplifier configured to amplify an input signal and output an amplified signal to an output terminal; and a stub configured to include a left-handed line, and an end connected to a node in a line between the amplifier and the output terminal; wherein when any frequency in an operating band is set as a fundamental wave and an impedance when the stub is viewed from the node is represented on a Smith chart, an impedance in a second harmonic wave is located at a first point where the impedance is short, and an impedance in a third harmonic wave rotates clockwise from the first point and is located at a point rotated by a smaller angle than a second point where the impedance is open. This can widen the band of the amplifier circuit.

Specific examples of an amplifier circuit according to embodiments of the present disclosure will be described below with reference to the drawings. It should be noted that the present disclosure is not limited to these examples, but is defined by the claims and is intended to include all modifications within the meaning and scope equivalent to the claims.

In an amplifier circuit used in a base station of the mobile communication, a Doherty amplifier circuit is used. In the Doherty amplifier circuit, an impedance converter using a λ/4 line is used in a combiner that combines high frequency signals amplified by a main amplifier and a peak amplifier with each other. Here, λ is a wavelength of the operation band. Therefore, the operating band is determined by the λ/4 line, and it is difficult to widen the operating band. In the load modulation type amplifier circuit, the operating band can be widened. However, the harmonic processing circuit cannot widen the band of the attenuation of the second harmonic wave. Therefore, it is difficult to widen the operating band of the load modulation type amplifier circuit.

### First Embodiment

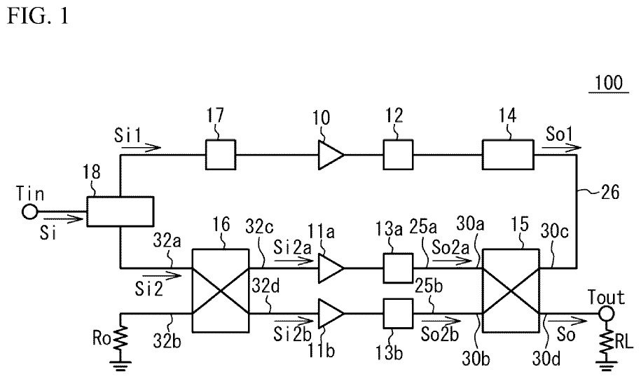

The first embodiment is an example of a LMBA (Load Modulated Balanced Amplifier). FIG. 1 is a circuit diagram of an amplifier circuit according to a first embodiment. As illustrated in FIG. 1, in an amplifier circuit 100 of the first embodiment, a control amplifier 10 and auxiliary amplifiers 11a and 11b are connected in parallel between an input terminal Tin and an output terminal Tout. A high-frequency signal is input to the input terminal Tin as an input signal Si. When the amplifier circuit 100 is used in a base station of the mobile communication, the frequency of the high frequency signal is, for example, 0.5 GHz or more and 10 GHz or less. A divider 18 (first divider) divides the input signal Si input to the input terminal Tin into signals Si1 (first signal) and Si2 (second signal).

The signal Si1 passes through a phase adjustment circuit 17 and is input to the control amplifier 10. The phase adjustment circuit 17 is a circuit that adjusts the phases of a signal So1 and signals So2a and So2b. A matching circuit for matching the impedances may be provided between the divider 18 and the control amplifier 10. The control amplifier 10 amplifies the signal Si1 and outputs the amplified signal as the signal So1 (third signal). The signal So1 amplified by the control amplifier 10 is output to an end 30c of a load modulation circuit 15 through a harmonic processing circuit 12 and a matching circuit 14. The matching circuit 14 matches an impedance when the matching circuit 14 is viewed from the control amplifier 10 with an impedance when the load modulation circuit 15 is viewed from the matching circuit 14. A line 26 is provided between the control amplifier 10 and the load modulation circuit 15. The harmonic processing circuit 12 suppresses a second harmonic component of the signal So1 passing through the line 26.

The signal Si2 divided by the divider 18 is further divided into the signals Si2a and Si2b by a divider 16. The divider 16 is, for example, a hybrid coupler. Ends 32a to 32d are terminals of the hybrid coupler, the ends 32a and 32d are diagonal terminals, and the ends 32b and 32c are diagonal terminals. The signal Si2 input to the end 32a is output to the ends 32c and 32d as the signals Si2a and Si2b, respectively. The phase of the signal Si2b is delayed by 90° from the phase of the signal Si2a. The amplitudes of the signals Si2a and Si2b are substantially the same as each other. The end 32b is terminated by a reference load Ro. In this way, the divider 16 (second divider) generates the signal Si2a (fifth signal) and the signal Si2b (sixth signal) whose phase is delayed by 90° from the signal Si2a, from the signal Si2.

The auxiliary amplifier 11a (first amplifier) amplifies the signal Si2a and outputs the amplified signal as the signal So2a (seventh signal). The auxiliary amplifier 11b (second amplifier) amplifies the signal Si2b and outputs the amplified signal as the signal So2b (eighth signal). The auxiliary amplifiers 11a and 11b have substantially the same size, and the operating points of the auxiliary amplifiers 11a and 11b are substantially the same. Matching circuits for matching impedances may be provided between the divider 16 and the auxiliary amplifier 11a and between the divider 16 and the auxiliary amplifier 11b, respectively. A line 25a is provided between the auxiliary amplifier 11a and the load modulation circuit 15. A line 25b is provided between the auxiliary amplifier 11b and the load modulation circuit 15. The harmonic processing circuits 13a and 13b suppress the second harmonic components of the signals So2a and So2b passing through the lines 25a and 25b, respectively.

The load modulation circuit 15 is, for example, a hybrid coupler. Ends 30a to 30d are terminals of the hybrid coupler, the ends 30a and 30d are diagonal terminals, and the ends 30b and 30c are diagonal terminals. The signals So2a and So2b are input to the ends 30a and 30b, respectively. The signal So1 is input to the end 30c. An output signal So is output from the end 30d to the output terminal Tout. The output terminal Tout is grounded via a load resistor RL. The load resistance RL is, for example, 50Ω. Bias circuits for supplying a bias voltage to the control amplifier 10 and the auxiliary amplifiers 11a and 11b is not illustrated.

Each of the control amplifier 10 and the auxiliary amplifiers 11a and 11b is, for example, a FET (Field Effect Transistors), and has a source connected to a ground, a gate to which the high frequency signal is input, and a drain to which the high frequency signal is output. The FET is, for example, a GaN HEMT (Gallium Nitride High Electron Mobility Transistor) or an LDMOS (Laterally Diffused Metal Oxide Semiconductor). Each of the control amplifier 10 and the auxiliary amplifiers 11a and 11b may be provided with multistage FETs.

The control amplifier 10 operates in class AB or class B, and the auxiliary amplifiers 11a and 11b operate in class C. When the input power of the input signal Si is small, the control amplifier 10 mainly amplifies the input signal Si. When the input power Si is increased, the auxiliary amplifiers 11a and 11b amplify the peak of the input signal Si in addition to the control amplifier 10. As a result, the control amplifier 10 and the auxiliary amplifiers 11a and 11b amplify the input signal Si.

When the power of the input signal Si is small and the auxiliary amplifiers 11a and 11b do not operate, the signal So1 input from the end 30c to the load modulation circuit 15 is divided into two signals So1/2 at the ends 30a and 30b, respectively. The phase of the signal So1/2 at the end 30b is delayed by 90° from the phase of the signal So1/2 at the end 30a. The signals So1/2 are reflected at the ends 30a and 30b. The signals So1/2 are combined at the end 30d. The phase of the signal So1/2 reflected at the end 30a is delayed by 90° from the phase of the signal So1/2 reflected at the end 30b. As a result, the phases of the two signals So1/2 are aligned at the end 30d to combine the two signals So1/2 with the signal So1. The combined signal So1 is output to the output terminal Tout as the output signal So. At this time, a reflection coefficient when the load modulation circuit 15 is viewed from the auxiliary amplifiers 11a and 11b is greater than 1, and the load impedances of the auxiliary amplifiers 11a and 11b are substantially high.

When the power of the input signal Si is large and the auxiliary amplifiers 11a and 11b operate, the phase of the signal So2b is delayed by 90° from the phase of the signal So2a. The phase of the signal So1/2 at the end 30b is delayed by 90° from the phase of the signal So1/2 at end 30a. Accordingly, the phase adjustment circuit 17 appropriately adjusts the phase of the signal Si1, so that the phases of the signals So2a and So1/2 at the end 30a are aligned, and the phases of the signals So2b and So1/2 at the end 30b are aligned. The signal So2a+So1/2 combined at the end 30a and the signal So2b+So1/2 combined at the end 30b are combined at the end 30d. The combined signal So1+So2a+So2b is output to the output terminal Tout as the output signal So. At this time, the reflection coefficient when the load modulation circuit 15 is viewed from the auxiliary amplifiers 11a and 11b is smaller than 1, and is reduced as the amplitudes of the signals So2a and So2b are larger. Therefore, the load impedances of the auxiliary amplifiers 11a and 11b are substantially reduced. In this way, the load modulation circuit 15 modulates the load impedances when the load modulation circuit 15 is viewed from the auxiliary amplifiers 11a and 11b depending on the amplitudes of the signals So2a and So2b.

### [Example of Load Modulation Circuit]

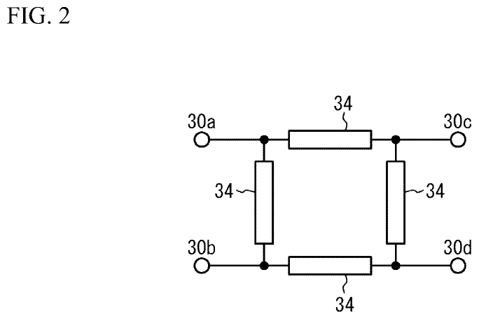

FIG. 2 is a circuit diagram illustrating an example of a circuit of the hybrid coupler according to the first embodiment. As illustrated in FIG. 2, transmission lines 34 are connected between ends 30a and 30b, between ends 30b and 30d, between ends 30d and 30c, and between ends 30c and 30a, respectively. The transmission line 34 has an electric length of ¼ of the wavelength A of the fundamental wave. As described above, the distributed constant type branch line coupler can be used as the hybrid coupler. The hybrid coupler may be a concentrated multiplier type branch line coupler using a capacitor and an inductor. The load modulation circuit 15 may be a distributed coupling coupler in which two λ/4 lines are electromagnetically coupled, or a close-wound coil coupler in which two inductors are electromagnetically coupled. As the divider 16, a Wilkinson type divider and a λ/4 line may be used in addition to the hybrid coupler.

### First Comparative Example

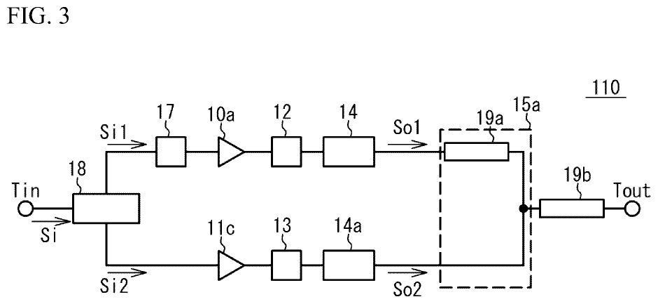

As a first comparative example, a Doherty amplifier circuit will be described. FIG. 3 is a circuit diagram of an amplifier circuit according to the first comparative example. As illustrated in FIG. 3, in an amplifier circuit 110 of the first comparative example, a main amplifier 10a and a peak amplifier 11c are provided in parallel between the input terminal Tin and the output terminal Tout. The divider 18 divides the input signal Si into signals Si1 and Si2. The main amplifier 10a amplifies the signal Si1 that has passed through the phase adjustment circuit 17, and outputs the amplified signal So1 to a combiner 15a via the harmonic processing circuit 12 and the matching circuit 14. The peak amplifier 11c amplifies the signal Si2 and outputs the amplified signal So2 to the combiner 15a via a harmonic processing circuit 13 and a matching circuit 14a. The combiner 15a combines the signals So1 and So2 and outputs the combined signal as the output signal So.

The combiner 15a includes λ/4 lines 19a and 19b as impedance converters. The load impedance of the peak amplifier 11c is modulated using the λ/4 lines 19a and 19b. In this case, when the frequency changes, the electrical lengths of the λ/4 lines shift from λ/4, and therefore it is difficult to widen the operating band. In one example, the specific bandwidth of the combiner using the λ/4 lines 19a and 19b is about 8%. In the LMBA of the first embodiment, the load impedances of the auxiliary amplifiers 11a and 11b are modulated by using the hybrid coupler, so that the operating band can be widened. The specific bandwidth of the hybrid coupler is, for example, 120% at the maximum in commercially available hybrid couplers. In this way, the LMBA allows the combiner to have a wide band.

### [Example of Harmonic Processing Circuit]

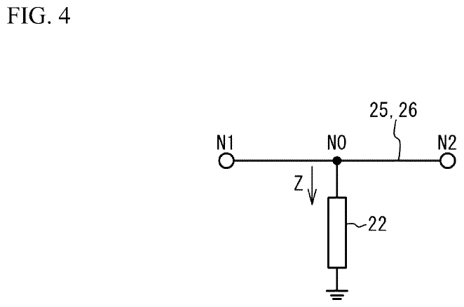

FIG. 4 is a circuit diagram illustrating an example of a harmonic processing circuit according to the first embodiment. As illustrated in FIG. 4, the line 26 or 25 is provided between nodes N1 and N2. A first end of a stub 22 is connected to the node NO in the line 26 or 25.

### Second Comparative Example: Stub of Right-Handed Line

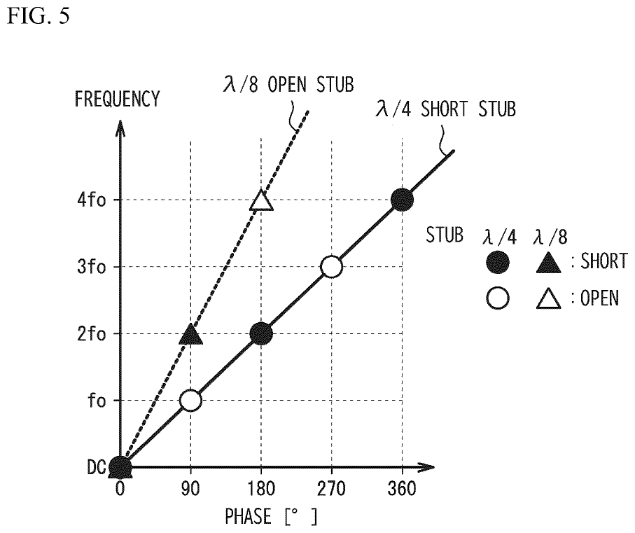

As a second comparative example, an example in which stubs of right-handed lines are used for the harmonic processing circuits 12, 13a, and 13b will be described. The right-handed line is a line made of a material having a positive dielectric constant, and is formed by a transmission line. In the second comparative example, a λ/8 open stub and a λ/4 short stub are used. The “A” is the wavelength of the fundamental wave. FIG. 5 is a diagram illustrating frequencies with respect to phases in the λ/4 short stub and the λ/8 open stub of a right-handed system. The phase of a horizontal axis represents a phase (i.e., phase difference) when a signal output from the node N0 to the stub 22 reaches a tip of the stub 22. A vertical axis represents a frequency of the signal. The frequencies of a direct current (DC), a fundamental wave, a second harmonic wave, a third harmonic wave, and a fourth harmonic wave are DC, fo, 2fo, 3fo, and 4fo, respectively. A solid line represents the λ/4 short stub and the dashed line represents the λ/8 open stub.

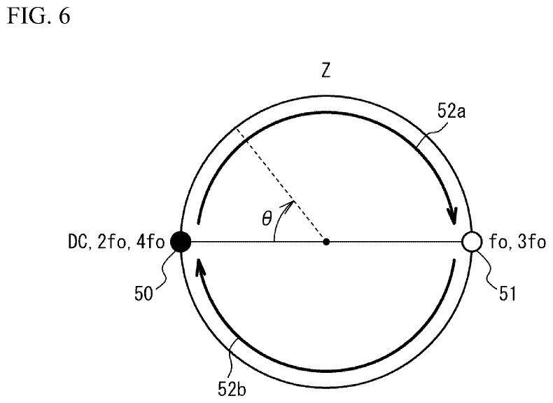

FIG. 6 is a Smith chart illustrating an impedance Z when the λ/4 short stub is viewed from the node N0 according to the second comparative example. A left end of the Smith chart is a point 50 indicative of short, and a right end thereof is a point 51 indicative of open. A straight line corresponds to a real axis. A center of a circle corresponds to a reference impedance, and an outer periphery of the circle corresponds to a fact that an absolute value (i.e., reflection coefficient) of the impedance Z normalized by the reference impedance is 1. As illustrated in FIG. 6, in the signal of the DC, the impedance Z is short and is located at the point 50. As the frequency of the signal increases from the DC, the impedance Z rotates clockwise by an angle θ, as indicated by an arrow 52a. In the fundamental wave fo, a distance between the node NO and the tip of the stub 22 corresponds to 90° in terms of the phase. At this time, the impedance Z is the point 51 indicative of the open. As the frequency further increases, the impedance Z rotates clockwise as indicated by an arrow 52b. In the second harmonic wave 2fo, the distance between the node N0 and the tip of the stub 22 corresponds to 180° in terms of the phase. The impedance Z is the point 50 of the short. In the third harmonic wave 3fo and the fourth harmonic wave 4fo, the phases are 270° and 360°, respectively, and the impedances Z are located at the point 51 indicative of the open and the point 50 indicative of the short, respectively.

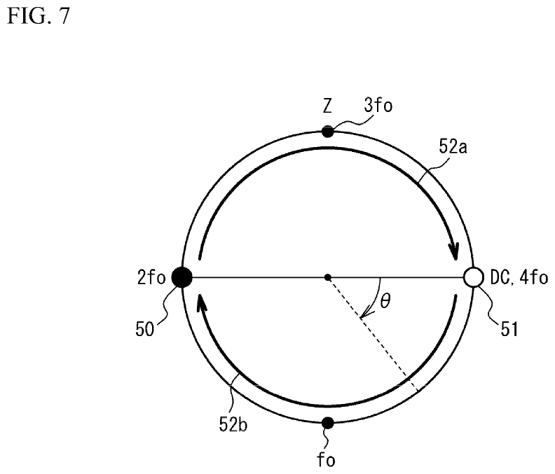

FIG. 7 is a Smith chart illustrating an impedance Z when the λ/8 open stub is viewed from the node N0 according to the second comparative example. As illustrated in FIG. 7, in the signal of the DC, the impedance Z is open and is located at the point 51. As the frequency of the signal increases from the DC, the impedance Z rotates clockwise by an angle θ as indicated by the arrow 52b. In the fundamental wave fo, the distance between the node N0 and the tip of the stub 22 corresponds to 45° in terms of the phase. At this time, the impedance Z is located at a lower end of the Smith chart. As the frequency increases, the impedance Z rotates clockwise. In the second harmonic wave 2fo, the distance between the node N0 and the tip of the stub 22 corresponds to 90° in terms of the phase. The impedance Z is the point 50 indicative of the short. In the third harmonic wave 3fo and the fourth harmonic wave 4fo, the phases are 135° and 180°, respectively, and the impedances Z are located at an upper end and the point 51 indicative of the open in the Smith chart, respectively.

As illustrated in FIGS. 5 to 7, the N4 short stub and the λ/8 open stub can short the impedance Z when the stub 22 is viewed from the node N0 in the second harmonic wave 2fo when the phases are 90° and 180°, respectively. As a result, the signals of the second harmonic wave 2fo passing through the lines 26, 25a and 25b are reflected at the node N0. This makes it possible to increase the reflection coefficient of the second harmonic wave 2fo.

However, in the λ/8 open stub, the impedance Z is not located at the point 51 indicative of the open, in the fundamental wave fo. This causes the reflection of the fundamental wave fo transmitted through the lines 26, 25a and 25b, and increases the loss. In the λ/4 short stub, the impedance is located at the point 51 indicative of the open, in the fundamental wave fo. The λ/4 short stub has a larger change in phase with respect to frequency than the λ/8 open stub. That is, when the frequency changes, the phase changes greatly. Therefore, the λ/4 short stub has a narrower band than the λ/8 open stub. As described above, when the λ/8 open stub is used in the harmonic processing circuits 12 and 13, the loss at the frequency of the fundamental wave fo becomes large. When the λ/4 short stub is used for the harmonic processing circuits 12 and 13, the band for processing the second harmonic wave is narrowed.

### [Description of Stub of Left-Handed Line]

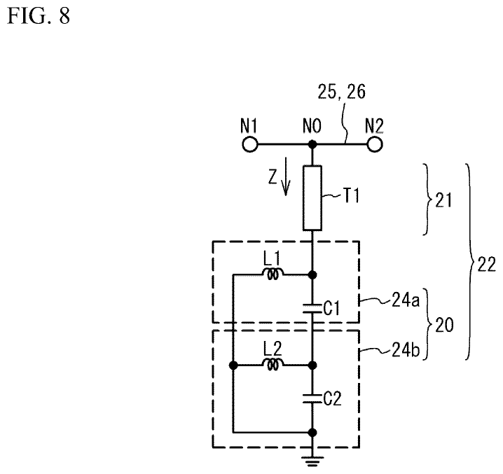

FIG. 8 is a circuit diagram of a stub in the first embodiment. A left-handed line is a line corresponding to a material having a negative dielectric constant, and can be realized in a pseudo manner by using a capacitor and an inductor. As illustrated in FIG. 8, the stub 22 includes a left-handed line 20 including two cells 24a and 24b. The cell 24a includes a capacitor C1 connected in series and an inductor L1 connected in shunt. The cell 24b includes a capacitor C2 connected in series and an inductor L2 connected in shunt. The stub 22 includes a right-handed line 21. The right-hand line 21 is, for example, a transmission line T1. The stub 22 may not include the right-handed line 21. However, when the transmission line T1 for connecting the node N0 to the cell 24a is provided, the stub 22 includes the right-handed line 21.

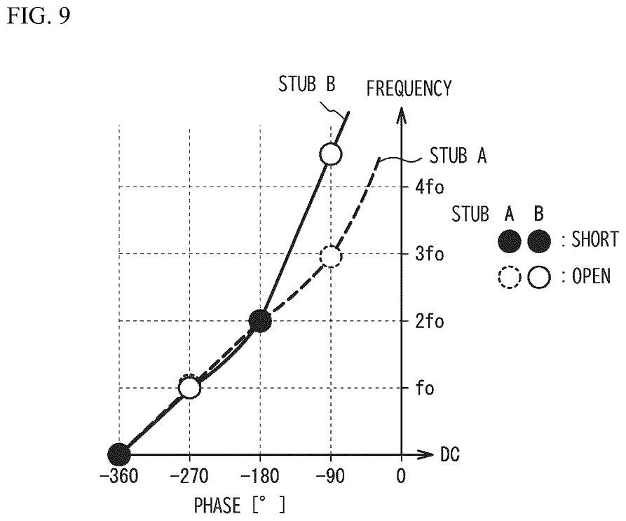

FIG. 9 is a diagram illustrating frequencies with respect to phases in stubs A and B. The stub A is a stub corresponding to the second comparative example, and the stub B is a stub corresponding to the first embodiment. As illustrated in FIG. 9, in the left-handed line, the frequency is infinite when the phase is 0°. In the line including the right-hand line, the frequency becomes finite due to the influence of the right-hand line. As the phase increases in the negative direction, the frequency decreases. In the left-handed line including n cells, 2n−1 negative order resonances can be set. The −1st, −2nd and −3rd order resonances can be set at phases of −90°, −180° and −270°, respectively, and the frequency is the DC when the phase is −360°. The frequencies at the phases of −90°, −180°, and −270° can be freely set by appropriately setting the capacitances of the capacitors C1 and C2 and the inductances of the inductors L1 and L2.

In the stub A, the frequencies at the phases of −90°, −180°, and −270° are set to be the third harmonic wave 3fo, the second harmonic wave 2fo, and the fundamental wave fo, respectively. In the stub B, the frequencies at the phases of −90°, −180°, and −270° are set to be a frequency higher than the fourth harmonic wave 4fo, the second harmonic wave 2fo, and the fundamental wave fo, respectively.

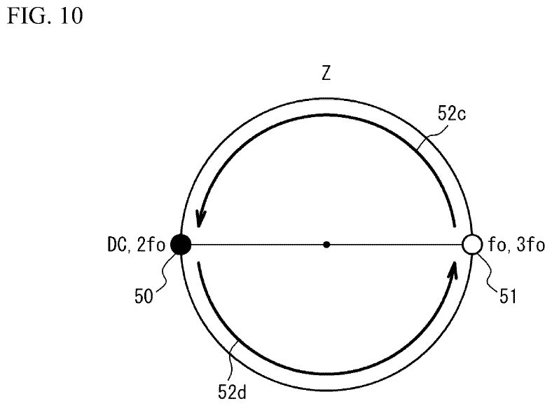

FIG. 10 is a Smith chart illustrating the impedance Z when the stub A is viewed from the node N0. As illustrated in FIG. 10, when the phase is −90°, the impedance Z is located at the point 51 indicative of the open, in the third harmonic wave 3fo. As the frequency decreases, the phase increases in the negative direction. As indicated by arrow 52c, the impedance Z rotates counterclockwise (i.e., counterclockwise) on the Smith chart. When the phase is −180°, the impedance Z is located at the point 50 indicative of the short, in the second harmonic wave 2fo. As the frequency decreases, the phase increases in the negative direction. As indicated by arrow 52d, the impedance Z rotates counterclockwise on the Smith chart. When the phase is −270°, the impedance Z is located at the point 51 indicative of the open, in the fundamental wave fo. Further, the frequency decreases, and in the DC, the phase is −360°, and the impedance Z is located at the point 50 indicative of the short.

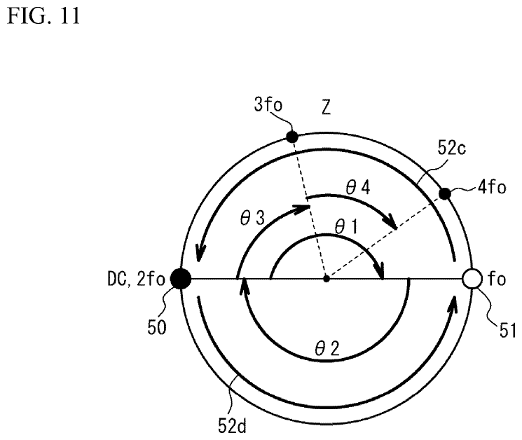

FIG. 11 is a Smith chart illustrating the impedance Z when the stub B is viewed from the node N0. As illustrated in FIG. 11, when the phase is −90°, the impedance Z is located at the point 51 indicative of the open at a frequency higher than the fourth harmonic wave 4 fo. As the frequency decreases, the phase increases in the negative direction. As indicated by an arrow 52c, the impedance Z rotates counterclockwise on the Smith chart. When the phase is −180°, the impedance Z is located at the point 50 indicative of the short, in the second harmonic wave 2fo. In the fourth harmonic wave 4fo and third harmonic wave 3fo, the phase is between −90° and −180°, and the impedance Z is located near the outer periphery of the upper half of the Smith chart. The positions of the impedance Z at the fundamental waves fo and the DC on the Smith chart are the same as those of the impedance Z of the stub A in FIG. 10.

From a different perspective, consider increasing the frequency from when the frequency is the DC. In the DC, the phase is −360°. On the Smith chart, the impedance Z is located at the point 50 indicative of the short. When the frequency changes from the DC to the fundamental wave fo, the impedance Z rotates clockwise by an angle θ1 on the Smith chart. The angle θ1 is approximately 180°. When the frequency changes from the fundamental wave fo to the second harmonic wave 2fo, the impedance Z rotates clockwise by an angle θ2 on the Smith chart. The angle θ2 is approximately 180°. When the frequency changes from the second harmonic wave 2fo to the third harmonic wave 3fo, the impedance Z rotates clockwise by an angle θ3 on the Smith chart. The angle θ3 is smaller than 180°, for example, 90° or less. When the frequency changes from the third harmonic wave 3fo to the fourth harmonic wave 4fo, the impedance Z rotates clockwise by an angle θ4 on the Smith chart. The angle θ 4 is smaller than 180°, for example, 90° or less.

As illustrated in FIG. 9, the change in phase with respect to the frequency can be made smaller in the stub B than in the stub A, in the second harmonic wave 2fo. Thus, when the stub B is used in the harmonic processing circuits 12 and 13, the band for processing the second harmonic wave can be widened.

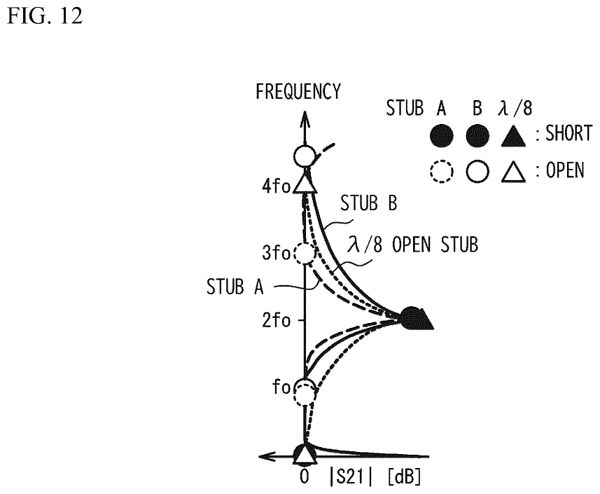

FIG. 12 is a diagram illustrating the passing characteristics of a line having the λ/8 open stub, a line having the stubs A, and a line having the stub B. A horizontal axis represents a passing characteristic when the node N2 is viewed from the node N1 in FIGS. 4 and 8, and corresponds to a value where |S21| is expressed in dB when the nodes N1 and N2 are a port 1 and a port 2, respectively. A vertical axis represents a frequency.

As illustrated in FIG. 12, in the λ/8 open stub and the stubs A and B, the impedance Z when the stub 22 is viewed from the node N0 is short and |S21| increases in the negative direction, in the second harmonic wave 2fo. Therefore, a signal passing from the node N1 to the node N2 is mostly reflected at the node N0. When the impedance Z is open, the signal passing from the node N1 to the node N2 is not affected by the stub 22, and the |S21| becomes substantially 0, and an insertion loss decreases. However, in the λ/8 open stub, frequencies at which the impedance Z is open are the DC and the fourth harmonic wave 4fo. Therefore, the |S21| increases in the negative direction at the fundamental wave fo. Accordingly, the insertion loss increases at the fundamental wave fo.

In the stub A, the impedance Z is open at the fundamental wave fo and the third harmonic wave 3fo. Therefore, the signal passing from the node N1 to the node N2 is not affected by the stub 22, and the |S21| becomes substantially 0, and the insertion loss decreases. However, as illustrated in FIG. 9, in the stub A, the change in phase with respect to the frequency increases in the vicinity of the second harmonic wave 2fo, and therefore the band of the stub A in which the |S21| can increase in the negative direction is smaller than that of the λ/8 open stub. Therefore, the band of the stub A capable of processing the second harmonic wave 2fo becomes narrow.

In the stub B, the impedance Z is open at the fundamental wave fo. Therefore, the signal passing from the node N1 to the node N2 is not affected by the stub 22, and the |S21| becomes substantially 0, and the insertion loss decreases. Furthermore, a frequency at which the impedance Z is open is higher than the fourth harmonic wave 4fo. Therefore, in the stub B, the change in phase with respect to the frequency can be decreased in the vicinity of the second harmonic wave 2fo. The band of the stub B in which the |S21| can increase in the negative direction is wider than that of the stub A. Therefore, the band of the stub B capable of processing the second harmonic wave 2fo can be made larger than that of the stub A.

### First Modification of First Embodiment

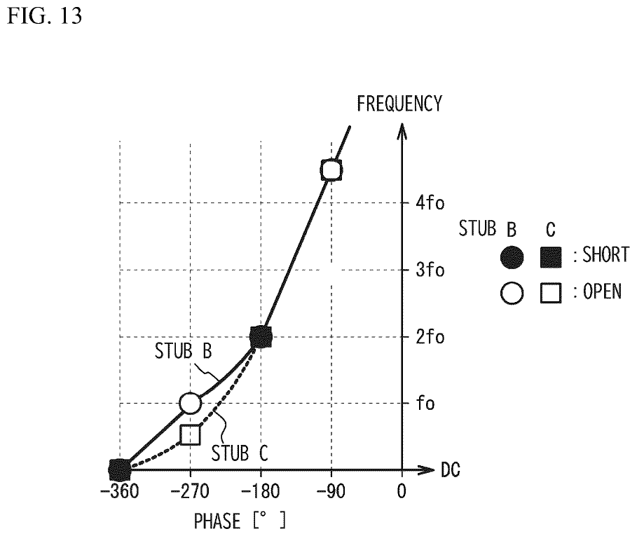

As a first modification of the first embodiment, an example in which the stub 22 is used as a stub C will be described. FIG. 13 is a diagram illustrating frequencies with respect to phases in the stubs B and C. The stub C is a stub corresponding to the first modification of the first embodiment. As illustrated in FIG. 13, in the stub C, the frequency of the −3rd order resonance at the phase of −270° is located between the DC and the fundamental wave fo. Therefore, the change in phase with respect to the frequency of the stub C between the fundamental wave fo and the second harmonic wave 2fo is smaller than that of the stub B. The other parts of FIG. 13 are the same as those of FIG. 9, and the description thereof is omitted.

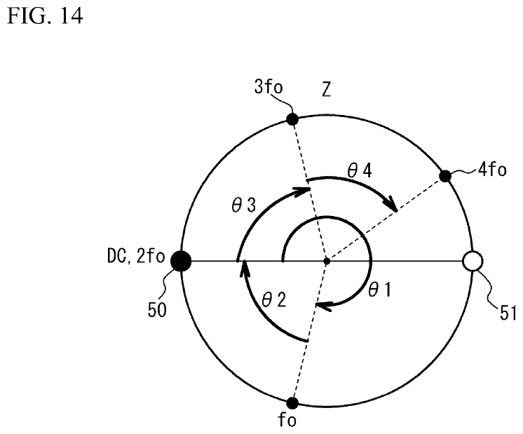

FIG. 14 is a Smith chart illustrating the impedance Z when the stub C is viewed from the node N0. As illustrated in FIG. 14, at the DC, the impedance Z is located at the point 50 indicative of the short on the Smith chart. When the frequency changes from the DC to the fundamental wave fo, the impedance Z rotates clockwise by an angle θ1 on the Smith chart. The angle θ1 is larger than 180°. At a frequency between the DC and the fundamental wave fo, the impedance Z is located at the point 51 indicative of the open. When the frequency changes from the fundamental wave fo to the second harmonic wave 2fo, the impedance Z rotates clockwise by an angle θ2 on the Smith chart. The angle θ2 is smaller than 180°, and an angle θ1+02 is approximately 360°. At the frequency of the second harmonic wave 2fo, the impedance Z is located at the point 50 indicative of the short. When the frequency changes from the second harmonic wave 2fo to the third harmonic wave 3fo, the impedance Z rotates clockwise by an angle θ3 on the Smith chart. The angle θ3 is smaller than 180°, for example, 90° or less. When the frequency changes from the third harmonic wave 3fo to the fourth harmonic wave 4fo, the impedance Z rotates clockwise by an angle θ4 on the Smith chart. The angle θ4 is smaller than 180°, for example, 90° or less.

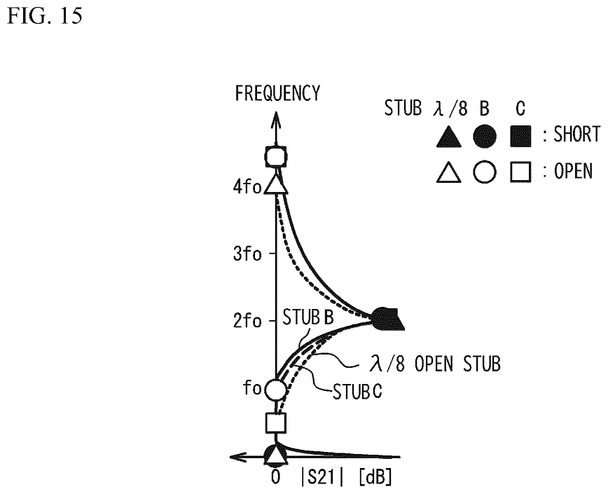

FIG. 15 is a diagram illustrating the passing characteristics of a line having the λ/8 open stub, a line having the stub B, and a line having the stub C. As illustrated in FIG. 15, in the stub C, since impedance Z is not open in the fundamental wave fo, the |S21| in the fundamental wave fo increases in the negative direction, However, since the impedance Z is located at the point 51 indicative of the open between the DC and the fundamental wave fo, the |S21| in the fundamental wave fo is smaller in the negative direction than that in the λ/8 open stub. Thereby, the insertion loss in the fundamental wave fo is smaller than that in the λ/8 open stub. As illustrated in FIG. 13, the change in phase with respect to the frequency in the second harmonic wave 2fo can be smaller in the stub C than in the stub B. Thereby, at a frequency lower than the second harmonic wave 2fo, the band of the stub C for attenuating the second harmonic wave 2fo can be made wider than that of the stub B. As in the first modification of the first embodiment, the frequency of the −3rd order resonance may be between the DC and the fundamental wave fo.

### [Simulation]

The passing characteristics |S21| of the lines 26, 25a and 25b were simulated for the λ/8 open stub, the stub A, and the stub C. The conditions for the stubs A and C are as follows.

### Stub A

Capacitor C1: 0.3 pF
Inductor L1: 4.7 nH
Capacitor C2: 0.1 pF
Inductor L2: 1 nH
Transmission line T1: Characteristic impedance at a frequency of 3.5 GHz is 80 Ω, and electrical length is 9° in terms of phase.

### Stub C

Capacitor C1: 0.8 pF
Inductor L1: 2.2 nH
Capacitor C2: 0.4 pF
Inductor L2: 0.2 nH
Transmission line T1: Characteristic impedance at a frequency of 3.5 GHz is 80Ω, and electrical length is 8° in terms of phase.

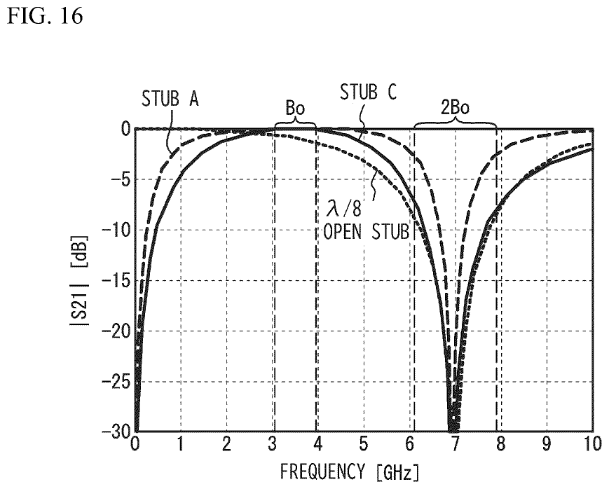

FIG. 16 is a diagram illustrating |S21| with respect to frequencies of the line having the λ/8 open stub, the line having the stub B, and the line having the stub C in simulation. A horizontal axis indicates the frequency of the high frequency signal input to the lines 26, 25a and 25b from the node N1 in FIGS. 4 and 8. A vertical axis represents the passing characteristic of the high frequency signal from the node N1 to the node N2 in FIGS. 4 and 8, and represents the |S21|. A band Bo is a band of the fundamental wave fo, and a band 2bo is a band of the second harmonic wave 2fo. As illustrated in FIG. 16, in the λ/8 open stub, the |S211 is-8 dB or less at the ends of the band 2bo, and the signal in the band 2bo is suppressed. However, the |S21| in the band Bo is about-2 dB, and the insertion loss is increased. In the stub A, the |S21| in the band Bo is approximately 0 dB, and the insertion loss is decreased. However, the |S21| at the ends of the band 2bo is-2 dB, and the band for suppressing the second harmonic wave 2fo is narrow. In the stub C, the |S21| in the band Bo is approximately 0 dB, and the insertion loss is decreased. Further, the |S21| at the ends of the band 2bo is −7 dB, which can be made almost the same as the |S21| of the λ/8 open stub. In the simulation, the specific bandwidth of the amplifier circuit using the stub C was 27% when the center frequency of the operating band was 3.7 GHZ.

### Second Modification of First Embodiment

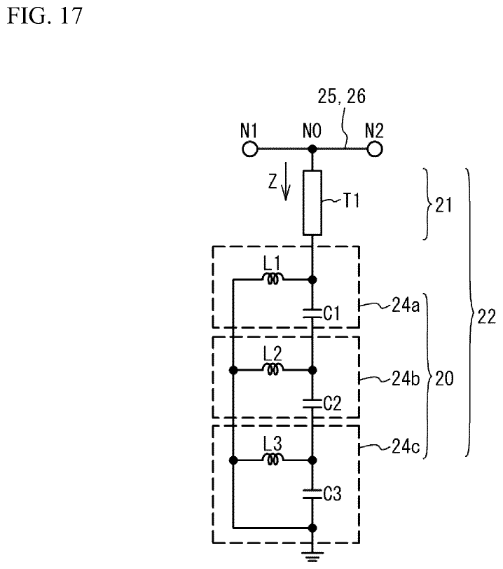

As a second modification of the first embodiment, an example in which the stub 22 is used as a stub D will be described. FIG. 17 is a circuit diagram of a stub in a second modification of the first embodiment. As illustrated in FIG. 17, the stub 22 which is the stub D includes the left-handed line 20 including three cells 24a to 24c. The cell 24c is positioned between the cell 24b and the tip of the stub 22, and includes a capacitor C3 connected in series and an inductor L3 connected in shunt. The other configurations are the same as those of FIG. 8 of the first embodiment, and the description thereof is omitted.

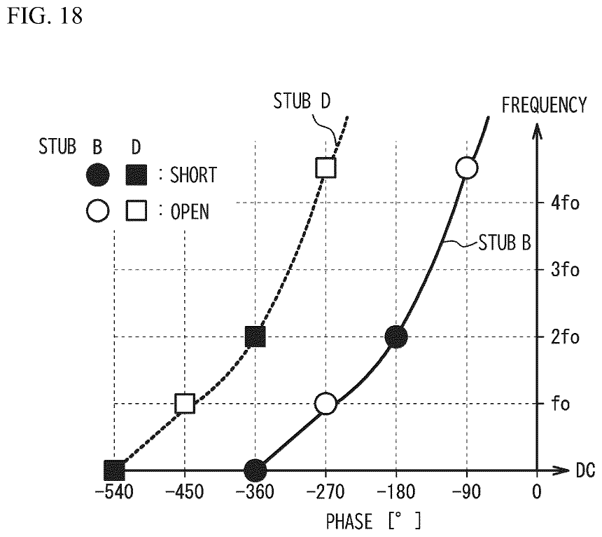

FIG. 18 is a diagram illustrating frequencies with respect to phases in the stubs B and D. As illustrated in FIG. 18, in the stub D, the number of cells is three, and five negative order resonances can be set. The −3rd, −4th and −5th order resonances have phases of −270°, −360° and −450°, respectively. The frequencies at the phases of −270°, −360° and −450° are set to a frequency higher than the fourth harmonic wave 4fo, the second harmonic wave 2fo and the fundamental wave fo, respectively. As a result, the stub D can widen the band for suppressing the second harmonic wave 2fo and suppress the insertion loss in the fundamental wave fo, similarly to the stub B.

### Second Embodiment

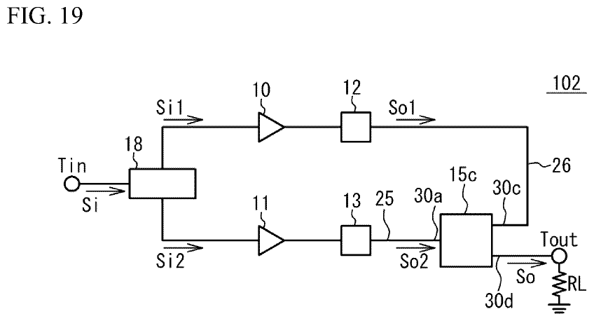

FIG. 19 is a circuit diagram of an amplifier circuit according to a second embodiment. As illustrated in FIG. 19, in an amplifier circuit 102 of the second embodiment, the divider 18 (first divider) divides the input signal Si input to the input terminal Tin into the signals Si1 (first signal) and Si2 (second signal). The signal Si1 is input to the control amplifier 10. The control amplifier 10 amplifies the signal Si1 and outputs the amplified signal as the signal So1 (third signal). The signal So1 amplified by the control amplifier 10 passes through the harmonic processing circuit 12 and is output to the end 30c of a load modulation circuit 15c.

The signal Si2 is input to an auxiliary amplifier 11. A matching circuit for matching the impedances may be provided between the divider 18 and the auxiliary amplifier 11. The auxiliary amplifier 11 amplifies the signal Si2 and outputs the amplified signal as the signal So2 (fourth signal). The signal So2 amplified by the auxiliary amplifier 11 passes through the harmonic processing circuit 13 and is output to the end 30a of the load modulation circuit 15c. In the load modulation circuit 15c, the signals So1 and So2 are combined, and the combined signal is output from the end 30d as the output signal So from the output terminal Tout.

When the power of the input signal Si is small and the auxiliary amplifier 11 does not operate, the impedance when the auxiliary amplifier 11 is viewed from the load modulation circuit 15c is substantially open. Therefore, the signal So1 input to the end 30c of the load modulation circuit 15c is reflected at the end 30a and output as the output signal So from the end 30d.

When the power of the input signal Si is large and the auxiliary amplifier 11 operates, the signal So2 is input to the end 30a and the signal So1 is reflected at the end 30a. A reflectance decreases as the power of the signal So2 increases. This reduces the load impedance when the load modulation circuit 15c is viewed from the auxiliary amplifier 11. In this way, the load of the auxiliary amplifier 11 is substantially adjusted by the power of the signal So2. That is, the load modulation circuit 15c modulates the load of the auxiliary amplifier 11 using the signal So1, combines the signals So1 and So2, and outputs the combined signal. Thus, the load impedance can be set so as to improve the characteristics of the auxiliary amplifier 11 in accordance with the magnitude of the power of the signal So2.

As the load modulation circuit 15c operating in this manner, for example, a circulator may be used in which a signal input to the end 30a is passed through the end 30d but not through the end 30c, a signal input to the end 30c is passed through the end 30a but not through the end 30d, and a signal input to the end 30d is passed through the end 30c but not through the end 30a.

According to the first and second embodiments and the modification thereof, as illustrated in FIGS. 1 and 19, the stub 22 has an end connected to the node N1 in at least one of the line 26 (first line) connecting the control amplifier 10 to the load modulation circuit 15 or 15c and the line 25 (second line) connecting the auxiliary amplifier 11 to the load modulation circuit 15 or 15c. As illustrated in FIGS. 8 and 17, the stub 22 includes the left-handed line 20.

As illustrated in the stubs B and C of FIGS. 11 and 14, when any frequency in the operating band is set as the fundamental wave fo and the impedance Z when the stub 22 is viewed from the node N0 is represented on the Smith chart, the impedance of the second harmonic wave 2fo is located at the point 50 (first portion) indicative of the short. The impedance Z in the third harmonic wave 3fo rotates clockwise from the point 50 and is located at a point rotated by a smaller angle than the point 51 (second point) indicative of the open. As a result, the frequency indicative of the open becomes larger than the third harmonic wave 3fo as illustrated in the stubs B and C of FIGS. 9 and 13. Therefore, the change in phase with respect to the frequency in the second harmonic wave 2fo can be reduced. As illustrated in FIGS. 12 and 15, the band of attenuation in the second harmonic wave 2fo can be widened. In addition, the insertion loss in the fundamental wave fo can be suppressed. Therefore, the band of the amplification circuit can be widened.

In FIGS. 11 and 14, the impedance Z in the third harmonic wave 3fo can be located at a point rotated by 135° or less clockwise from the point 50, or can be located at a point rotated by 90° or less clockwise from the point 50. As a result, as illustrated in FIGS. 12 and 15, the band of attenuation in the second harmonic wave 2fo can be widened.

The frequency of the fundamental wave fo may be any frequency in the operating band, but may be the frequency at the center of the operating band.

When the impedance Z is represented on the Smith chart as illustrated in stubs B and C of FIGS. 11 and 14, the impedance in the fourth harmonic wave 4fo rotates clockwise from the point 50 and is located at the point 51 or a point rotated by a smaller angle than the point 51. As a result, the frequency indicative of the open becomes equal to or more than the fourth harmonic wave 4fo as illustrated in the stubs B and C of FIGS. 9 and 13. Therefore, the change in phase with respect to the frequency in the second harmonic wave 2fo can be made smaller, and the band of attenuation in the second harmonic wave 2fo can be widened as illustrated in FIGS. 12 and 15.

When the impedance Z is represented on the Smith chart as illustrated in the stub B of FIG. 11, the impedance in the fundamental wave fo rotates clockwise from the point 50 and is located at the point 51. As a result, the frequency indicative of the open becomes the fundamental wave fo as illustrated in the stub B of FIG. 9. As illustrated in the stub B of FIG. 12, the frequency indicative of the open can be made closer to the frequency of the fundamental wave fo than the DC which is the frequency indicative of the open of the λ/8 open stub. This makes it possible to suppress the insertion loss in the fundamental wave fo.

When the impedance Z is represented on the Smith chart as illustrated in the stub C of FIG. 14, the impedance in the fundamental wave fo rotates clockwise from the point 50, and is located at a point rotated by a larger angle than the point 51 and a smaller angle than 360°. As a result, as illustrated in FIG. 15, although the insertion loss in the fundamental wave fo is slightly larger in the stub C than in the stub B, the band of attenuation in the second harmonic wave 2fo can be widened. The impedance in the fundamental wave fo can be set to a point rotated by 200° or more clockwise from the point 50, or can be set to a point rotated by 225° or more clockwise from the point 50. This makes it possible to further widen the band of attenuation in the second harmonic wave 2fo. The impedance of the fundamental wave fo can be set to a point rotated by 340° or less clockwise from the point 50, or can be set to a point rotated by 315° or less clockwise from the point 50. This makes it possible to further widen the band of attenuation in the second harmonic wave 2fo.

The point 50 indicative of the short and the point 51 indicative of the open may not be strictly the positions of the short and the open on the Smith chart. For example, when the periphery of the Smith chart is a circle having a reflection coefficient of 1, the Smith chart is represented by using polar coordinates, and the radius vector of the center of the Smith chart is set to 0 and the radius vector of the periphery of the Smith chart is set to 1. The position of the periphery of the right end on the real axis of the Smith chart is set to 0°, and a clockwise angle is set as a deflection angle. At this time, the radius vector of the point 50 indicative of the short is, for example, 0.65 or more and 1.0 or less, or 0.8 or more and 1.0 or less. The deflection angle is, for example, 135° or more and 225° or less, or 160° or more and 200° or less. The radius vector of the point 51 indicative of the open is, for example, 0.65 or more and 1.0 or less, or 0.8 or more and 1.0 or less. The deflection angle is, for example, 45° or less and 315° or more, or 20° or less and 340° or more.

As illustrated in FIG. 8, the left-handed line 20 includes the cell 24a (first cell) and the cell 24b (second cell). The cell 24a includes the capacitor C1 (first capacitor) connected in series and the inductor L1 (first inductor) connected in shunt between the node N0 and the tip of the stub 22. The cell 24b includes the capacitor C2 (second capacitor) connected in series and the inductor L2 (second inductor) connected in shunt between the cell 24a and the tip of the stub 22. In this way, by providing two cells, three negative order resonances can be set. Therefore, the band of the amplification circuit can be widened.

As illustrated in the stub D of FIG. 17, the left-handed line 20 may include the cell 24c (third cell) in addition to the cells 24a and 24b. The cell 24c includes the capacitor C3 (third capacitor) connected in series and the inductor L3 (third inductor) connected in shunt between the cell 24b and the tip of the stub 22. Thereby, five negative order resonances can be set. In order to reduce the size of the stub 22, the number of cells can be two.

As illustrated in FIG. 1, the node N0 to which the stub 22 is connected is provided in the line 25. This makes it possible to suppress the second harmonic wave in the signal So2 amplified by the auxiliary amplifier 11 over the wide band.

When the λ/8 open stub is used in the harmonic processing circuit 13, the insertion loss in the fundamental wave fo increases as illustrated in FIG. 12. Therefore, a matching circuit for matching the impedances is provided in the line 25 in order to suppress the insertion loss in the fundamental wave fo. Generally, an amplifier circuit is provided with a matching circuit at a stage subsequent to an amplifier. Therefore, the matching circuit at the stage subsequent to the amplifier can have a function of suppressing the insertion loss in the fundamental wave fo together with a function of matching the impedances. Therefore, in a general amplifier circuit, even if the λ/8 open stub is provided in the harmonic processing circuit, the restriction of the circuit is not large. On the other hand, in the load modulation type amplifier circuit, since the load modulation circuit 15 modulates the load of the auxiliary amplifier 11, the matching circuit need not be provided in the line 25. However, if the λ/8 open stub is used in the harmonic processing circuit 13, the matching circuit is provided on the line 25, and the circuit configuration is increased in size. Therefore, by using the stub 22 including the left-handed line as the harmonic processing circuit 13, it is not necessary to provide the matching circuit in the line 25. Therefore, the circuit configuration can be reduced in size.

In the first embodiment, as illustrated in FIGS. 1 and 2, the load modulation circuit 15 includes the end 30a (first end) to which the signal So2a is input, the end 30b (second end) to which the signal So2b is input, the end 30c (third end) which is located diagonally opposite to the end 30b and to which the signal So1 is input, and the end 30d (fourth end) which is located diagonally opposite to the end 30a and connected to the output terminal Tout. In the LMBA using the hybrid coupler as the load modulation circuit 15, the band of the load modulation circuit 15 for combining the signal So1 and the signals So2a and So2b can be widened.

In the second embodiment, as illustrated in FIG. 19, the load modulation circuit 15c includes the end 30a (first end) to which the signal So2 is input, the end 30c (second end) to which the signal So1 is input, and the end 30d (third end) to which the output signal So is output. The load modulation circuit 15c allows the signal input to the end 30a to pass through the end 30d and not through the end 30c, and the signal input to the end 30c to pass through the end 30a and not through the end 30d. This makes it possible to realize the load modulation circuit 15c without using a hybrid coupler, thereby reducing the size of the amplifier circuit and widening the band of the load modulation circuit 15c for combining the signals So1 and So2.

Although the load modulation type amplifier circuit is described as the amplifier circuit in the first and second embodiments and the modification thereof, the stub described in the first and second embodiments and the modification thereof may be used in an amplifier circuit other than the load modulation type amplifier circuit.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. An amplifier circuit comprising:
a first divider configured to divide an input signal into a first signal and a second signal;
a control amplifier configured to amplify the first signal and output an amplified signal as a third signal;
an auxiliary amplifier configured to amplify the second signal and output an amplified signal as a fourth signal;
a load modulation circuit configured to modulate a load of the auxiliary amplifier by using the third signal, combine the third signal and the fourth signal, and output a combined signal as an output signal; and
a stub configured to include a left-handed line, and an end connected to a node in at least one of a first line connecting the control amplifier to the load modulation circuit and a second line connecting the auxiliary amplifier to the load modulation circuit;
wherein when any frequency in an operating band is set as a fundamental wave and an impedance when the stub is viewed from the node is represented on a Smith chart, an impedance in a second harmonic wave is located at a first point where the impedance is short, and an impedance in a third harmonic wave rotates clockwise from the first point and is located at a point rotated by a smaller angle than a second point where the impedance is open.

2. The amplifier circuit according to claim 1, wherein
when the impedance when the stub is viewed from the node is represented on the Smith chart, an impedance in a fourth harmonic wave rotates clockwise from the first location and is located at the second point or a point rotated by a smaller angle than the second point.

3. The amplifier circuit according to claim 1, wherein
when the impedance when the stub is viewed from the node is represented on the Smith chart, an impedance in the fundamental wave rotates clockwise from the first point and is located at the second point.

4. The amplifier circuit according to claim 1, wherein
when the impedance when the stub is viewed from the node is represented on the Smith chart, an impedance in the fundamental wave rotates clockwise from the first point and is located at a point rotated by a larger angle than the second point.

5. The amplifier circuit according to claim 1, wherein
the node is provided in the second line.

6. The amplifier circuit according to claim 5, wherein
no matching circuit for matching impedances is provided in the second line.

7. The amplifier circuit according to claim 1, further comprising:
a second divider configured to divide the second signal into a fifth signal and a sixth signal whose phase is delayed by 90 degrees from the fifth signal;
wherein the auxiliary amplifier includes a first amplifier that amplifies the fifth signal and outputs an amplified signal as a seventh signal, and a second amplifier that amplifies the sixth signal and outputs an amplified signal as an eighth signal, and
the load modulator includes a hybrid coupler including a first end to which the seventh signal is input, a second end to which the eighth signal is input, a third end that is located diagonally opposite to the second end and to which the third signal is input, and a fourth end that is located diagonally opposite to the first end and to which the output signal is output.

8. The amplifier circuit according to claim 1, wherein
the load modulation circuit includes a first end to which the fourth signal is input, a second end to which the third signal is input, and a third end to which the output signal is output, and
a signal input to the first end is passed through the third end but not through the second end, and a signal input to the second end is passed through the first end but not through the third end.

9. The amplifier circuit according to claim 1, wherein
the left-handed line includes:
a first cell including a first capacitor connected in series and a first inductor connected in shunt between the node and a tip of the stub; and
a second cell including a second capacitor connected in series and a second inductor connected in shunt between the first cell and the tip of the stub.

10. The amplifier circuit according to claim 1, wherein
the left-handed line includes:
a first cell including a first capacitor connected in series and a first inductor connected in shunt between the node and a tip of the stub;
a second cell including a second capacitor connected in series and a second inductor connected in shunt between the first cell and the tip of the stub; and
a third cell including a third capacitor connected in series and a third inductor connected in shunt between the second cell and the tip of the stub.

11. An amplifier circuit comprising:
an amplifier configured to amplify an input signal and output an amplified signal to an output terminal; and
a stub configured to include a left-handed line, and an end connected to a node in a line between the amplifier and the output terminal;
wherein when any frequency in an operating band is set as a fundamental wave and an impedance when the stub is viewed from the node is represented on a Smith chart, an impedance in a second harmonic wave is located at a first point where the impedance is short, and an impedance in a third harmonic wave rotates clockwise from the first point and is located at a point rotated by a smaller angle than a second point where the impedance is open.
